(19) United States
(12) Patent Application Publication
(10) Pub. No.: US 2009/0213643 A1
(43) Pub. Date: Aug. 27, 2009

(54) Integrated Circuit and Method of Improved Determining a Memory State of a Memory Cell

(76) Inventors: Michael Angerbauer, Freutsmoos (DE); Heinz Hoenigschmid, Poecking (DE); Corvin Liaw, Muenchen (DE)

Correspondence Address: SLATER & MATSIL, L.L.P., 17950 PRESTON ROAD, SUITE 1000, DALLAS, TX, 75252, US

(21) Appl. No.: 12/037,785

(22) Filed: Feb. 26, 2008

(51) Int. Cl. G11C 11/00; G11C 11/34; G11C 7/00

(52) U.S. Cl. 365/163; 365/148; 365/174; 365/189.011

(57) ABSTRACT

According to one embodiment, a method of determining a memory state of a resistivity changing memory cell is provided. A first electrode of the resistivity changing memory cell is set to a first potential. The method further includes setting the second electrode to a second potential being different from the first potential, thereby generating a memory state sensing current flowing through the resistivity changing memory cell; controlling the strength of the second potential in dependence on the strength of the memory state sensing current such that the strength of the memory state sensing current is kept constant.

### TECHNICAL FIELD

Embodiments relate generally to a method and an integrated circuit of determining a memory state of a resistivity changing memory cell keeping the strength of a memory state sensing current constant.

### BACKGROUND

Information may be stored in a resistive memory cell, e.g., by changing the resistivity of the memory cell. When reading the information stored in the memory cell, usually the resistivity will not be changed in case some voltage conditions are kept. The information stored in a memory cell may be read by evaluating the resistivity of the memory cell or by evaluating the current flowing through the memory cell.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a computer system having a memory cell arrangement in accordance with an embodiment;

FIG. 2 shows a memory in accordance with an embodiment;

FIG. 3A shows a cross-sectional view of a solid electrolyte memory cell set to a first memory state in accordance with an embodiment;

FIG. 3B shows a cross-sectional view of a solid electrolyte memory device set to a second memory state in accordance with an embodiment;

FIG. 4 shows a cross-sectional view of a phase-changing memory cell in accordance with an embodiment;

FIG. 5 shows a schematic drawing of a memory device including resistivity changing memory cells in accordance with an embodiment;

FIG. 6 shows a method of determining a memory state of a resistivity changing memory cell according to an embodiment;

FIG. 7 shows a schematic drawing of a memory device according to an embodiment;

FIG. 8 shows a schematic drawing of a memory device according to an embodiment;

FIG. 9A shows a memory module according to an embodiment;

FIG. 9B shows a stackable memory module according to an embodiment;

FIG. 10A shows a cross-sectional view of a carbon memory cell set to a first switching state in accordance with an embodiment;

FIG. 10B shows a cross-sectional view of a carbon memory cell set to a second switching state in accordance with an embodiment;

FIG. 11A shows a schematic drawing of a resistivity changing memory cell in accordance with an embodiment; and

FIG. 11B shows a schematic drawing of a resistivity changing memory cell in accordance with an embodiment.

### DETAILED DESCRIPTION OF ILLUSTRATIVE EMBODIMENTS

As used herein the terms “connected” and “coupled” are intended to include both direct and indirect connection and coupling, respectively.

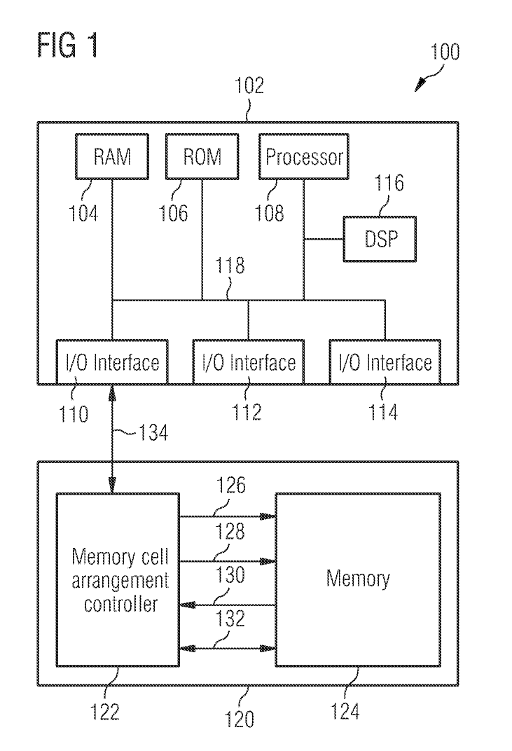

FIG. 1 shows a computer system 100 having a computer arrangement 102 and a memory cell arrangement 120 in accordance with an embodiment.

In various embodiments, the computer arrangement 102 may be configured as or may include any device having a processor, e.g., having a programmable processor such as, e.g., a microprocessor (e.g., a CISC (complex instruction set computer) microprocessor or a RISC (reduced instruction set computer) microprocessor). In various embodiments, the computer arrangement 102 may be configured as or may include a personal computer, a workstation, a laptop, a notebook, a personal digital assistant (PDA), a radio telephone (e.g., a wireless radio telephone or a mobile radio telephone), a camera (e.g., an analog camera or a digital camera), or another device having a processor (such as, e.g., a household appliance (such as, e.g., a washing machine, a dishwashing machine, etc.))

In an embodiment, the computer arrangement 102 may include one or a plurality of computer arrangement-internal random access memories (RAM) 104, e.g., one or a plurality of computer arrangement-internal dynamic random access memories (DRAM), in which, for example, data to be processed may be stored. Furthermore, the computer arrangement 102 may include one or a plurality of computer arrangement-internal read only memories (ROM) 106, in which, for example, the program code may be stored, which should be executed by a processor 108 (e.g., a processor as described above), which may also be provided in the computer arrangement 102.

Furthermore, in an embodiment, one or a plurality of input/output interfaces 110, 112, 114 (in FIG. 1, there are shown three input/output interfaces, in alternative embodiments, e.g., one, two, four, or even more than four input/output interfaces may be provided) configured to connect one or a plurality of computer arrangement-external devices (such as, e.g., additional memory, one or a plurality of communication devices, one or a plurality of additional processors) to the computer arrangement 102, may be provided in the computer arrangement 102.

The input/output interfaces 110, 112, 114 may be implemented as analog interfaces and/or as digital interfaces. The input/output interfaces 110, 112, 114 may be implemented as serial interfaces and/or as parallel interfaces. The input/output interfaces 110, 112, 114 may be implemented as one or a plurality of circuits, which implements or implement a respective communication protocol stack in its functionality in accordance with the communication protocol which is respectively used for data transmission. Each of the input/output interfaces 110, 112, 114 may be configured in accordance with any communication protocol. In an embodiment, each of the input/output interfaces 110, 112, 114 may be implemented in accordance with one of the following communication protocols:
an ad hoc communication protocol such as, e.g., Firewire or Bluetooth;
a communication protocol for a serial data transmission such as e.g. RS-232, Universal Serial Bus (USB) (e.g. USB 1.0, USB 1.1, USB 2.0, USB 3.0);
any other communication protocol such as, e.g., Infrared Data Association (IrDA).

In an embodiment, the first input/output interface 110 is a USB interface (in alternative embodiments, the first input/output interface 110 may be configured in accordance with any other communication protocol such as, e.g., in accordance with a communication protocol which has been described above).

In an embodiment, the computer arrangement 102 optionally may include an additional digital signal processor (DSP) 116, which may be provided, e.g., for digital signal processing. Furthermore, the computer arrangement 102 may include additional communication modules (not shown) such as, e.g., one or a plurality of transmitters, one or a plurality of receivers, one or a plurality of antennas, and so on.

The computer arrangement 102 may also include additional components (not shown), which are desired or required in the respective application.

In an embodiment, some or all of the circuits or components provided in the computer arrangement 102 may be coupled with each other by means of one or a plurality of computer arrangement-internal connections 118 (for example, by means of one or a plurality of computer busses) configured to transmit data and/or control signals between the respectively coupled circuits or components.

Furthermore, as has been described above, the computer system 100, in accordance with an embodiment, may include the memory cell arrangement 120.

The memory cell arrangement 120 may in an embodiment be configured as an integrated circuit. The memory cell arrangement 120 may further be provided in a memory module having a plurality of integrated circuits, wherein at least one integrated circuit of the plurality of integrated circuits includes a memory cell arrangement 120, as will be described in more detail below. The memory module may be a stackable memory module, wherein some of the integrated circuit may be stacked one above the other. In an embodiment, the memory cell arrangement 120 is configured as a memory card.

In an embodiment, the memory cell arrangement 120 may include a memory cell arrangement controller 122 (for example, implemented by means of hard wired logic and/or by means of one or a plurality of programmable processors, e.g., by means of one or a plurality of programmable processors such as, e.g., one or a plurality of programmable microprocessors (e.g., CISC (complex instruction set computer) microprocessor(s) or RISC (reduced instruction set computer) microprocessor(s)).

The memory cell arrangement 120 may further include a memory 124 having a plurality of memory cells. The memory 124 will be described in more detail below.

In an embodiment, the memory cell arrangement controller 122 may be coupled with the memory 124 by means of various connections. Each of the connections may include one or a plurality of lines and may thus have a bus width of one or a plurality of bits. Thus, by way of example, an address bus 126 may be provided, by means of which one or a plurality of addresses of one or a plurality of memory cells may be provided by the memory cell arrangement controller 122 to the memory 124, on which an operation (e.g., an erase operation, a write operation, a read operation, an erase verify operation, or a write verify operation, etc.) should be carried out. Furthermore, a data write connection 128 may be provided, by means of which the information to be written into the respectively addressed memory cell may be supplied by the memory cell arrangement controller 122 to the memory 124. Furthermore, a data read connection 130 may be provided, by means of which the information stored in the respectively addressed memory cell may be read out of the memory 124 and may be supplied from the memory 124 to the memory cell arrangement controller 122 and via the memory cell arrangement controller 122 to the computer arrangement 102, or, alternatively, directly to the computer arrangement 102 (in which case the first input/output interface 110 would directly be connected to the memory 124). A bidirectional control/state connection 132 may be used for providing control signals from the memory cell arrangement controller 122 to the memory 124 or for supplying state signals representing the state of the memory 124 from the memory 124 to the memory cell arrangement controller 122.

In an embodiment, the memory cell arrangement controller 122 may be coupled to the first input/output interface 110 by means of a communication connection 134 (e.g., by means of a USB communication connection).

In an embodiment, the memory 124 may include one chip or a plurality of chips. Furthermore, the memory cell arrangement controller 122 may be implemented on the same chip (or die) as the components of the memory 124 or on a separate chip (or die).

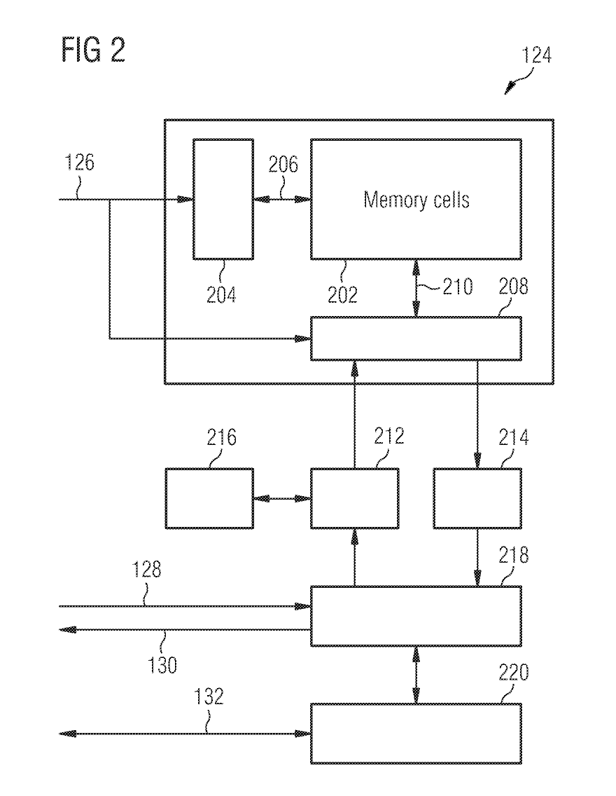

FIG. 2 shows the memory 124 of FIG. 1 in accordance with an embodiment in more detail.

In an embodiment, the memory 124 may include a memory cell field (e.g., a memory cell array) 202 having a plurality of memory cells. The memory cells may be arranged in the memory cell field 202 in the form of a matrix in rows and columns, or, alternatively, for example, in zig zag form. In other embodiments, the memory cells may be arranged within the memory cell field 202 in any other manner or architecture.

In general, each memory cell may, for example, be coupled with a first control line (e.g., a word line) and with at least one second control line (e.g., at least one bit line).

In an embodiment, in which the memory cells are arranged in the memory cell field 202 in the form of a matrix in rows and columns, a row decoder circuit 204 configured to select at least one row control line (e.g., a word line) of a plurality of row control lines 206 in the memory cell field 202 may be provided as well as a column decoder circuit 208 configured to select at least one column control line (e.g., a bit line) of a plurality of column control lines 210 in the memory cell field 202.

In an embodiment, the memory cells are non-volatile memory cells.

A “non-volatile memory cell” may be understood as a memory cell storing data even if it is not active. In an embodiment, a memory cell may be understood as being not active, e.g., if current access to the content of the memory cell is inactive. In another embodiment, a memory cell may be understood as being not active, e.g., if the power supply is inactive. Furthermore, the stored data may be refreshed on a regular timely basis, but not, as with a “volatile memory cell” every few picoseconds or nanoseconds or milliseconds, but rather in a range of hours, days, weeks or months. Alternatively, the data may not need to be refreshed at all in some designs.

The non-volatile memory cells may be memory cells selected from a group of memory cells consisting e.g. of:
charge storing random access memory cells (e.g., floating gate memory cells or charge trapping memory cells);
ferroelectric random access memory cells (FeRAM, FRAM);
magnetoresistive random access memory cells (MRAM);
phase change random access memory cells (PCRAM, for example, so called Ovonic Unified Memory (OUM) memory cells);
conductive filament random access memory cells (e.g., conductive bridging random access memory cells (CBRAM), also referred to as programmable metallization cells (PMC), or carbon-based conductive filament random access memory cells);
organic random access memory cells (ORAM);
nanotube random access memory cells (NRAM) (e.g., carbon nanotube random access memory cells);
nanowire random access memory cells.

In alternative embodiments, also other types of non-volatile memory cells may be used.

In various embodiments, the memory cells may be resistive memory cells.

Furthermore, the memory cells may be electrically erasable read only memory cells (EEPROM).

In an embodiment, the memory cells may be Flash memory cells, e.g., charge storing memory cells such as, e.g., floating gate memory cells or charge trapping memory cells.

In an embodiment, each charge trapping memory cell includes a charge trapping layer structure for trapping electrical charge carriers. The charge trapping layer structure may include one or a plurality of two separate charge trapping regions. In an embodiment, the charge trapping layer structure includes a dielectric layer stack including at least one dielectric layer or at least two dielectric layers being formed above one another, wherein charge carriers can be trapped in at least one dielectric layer. By way of example, the charge trapping layer structure includes a charge trapping layer, which may include or consist of one or more materials being selected from a group of materials that consists of: aluminum oxide (Al₂O₃), yttrium oxide (Y₂O₃), hafnium oxide (HfO₂), lanthanum oxide (LaO₂), zirconium oxide (ZrO₂), amorphous silicon (a-Si), tantalum oxide (Ta₂O₅), titanium oxide (TiO₂), and/or an aluminate. An example for an aluminate is an alloy of the components aluminum, zirconium and oxygen (AlZrO). In one embodiment, the charge trapping layer structure includes a dielectric layer stack including three dielectric layers being formed above one another, e.g., a first oxide layer (e.g., silicon oxide), a nitride layer as charge trapping layer (e.g., silicon nitride) on the first oxide layer, and a second oxide layer (e.g., silicon oxide or aluminum oxide) on the nitride layer. This type of dielectric layer stack is also referred to as ONO layer stack. In an alternative embodiment, the charge trapping layer structure includes two, four or even more dielectric layers being formed above one another.

In an embodiment, the memory cells may be multi-bit memory cells. As used herein the term “multi-bit” memory cell is intended to, e.g., include memory cells which are configured to store a plurality of bits by spatially separated electric charge storage regions or current conductivity regions, thereby representing a plurality of logic states.

In another embodiment, the memory cells may be multi-level memory cells. As used herein the term “multi-level” memory cell is intended to, e.g., include memory cells which are configured to store a plurality of bits by showing distinguishable voltage or current levels dependent on the amount of electric charge stored in the memory cell or the amount of electric current flowing through the memory cell, thereby representing a plurality of logic states.

In an embodiment, address signals are supplied to the row decoder circuit 204 and the column decoder circuit 208 by means of the address bus 126, which is coupled to the row decoder circuit 204 and to the column decoder circuit 208. The address signals uniquely identify at least one memory cell to be selected for an access operation (e.g., for one of the above described operations). The row decoder circuit 204 selects at least one row and thus at least one row control line 206 in accordance with the supplied address signal. Furthermore, the column decoder circuit 208 selects at least one column and thus at least one column control line 210 in accordance with the supplied address signal.

The electrical voltages that are provided in accordance with the selected operation, e.g., for reading, programming (e.g., writing) or erasing of one memory cell or of a plurality of memory cells, are applied to the selected at least one row control line 206 and to the at least one column control line 210.

In the case that each memory cell is configured in the form of a resistive memory cell having only two terminals, a first terminal of the resistive memory cell may be coupled to the row control line 206 and a second terminal of the resistive memory cell may be coupled to the column control line 210.

In the case that each memory cell is configured in the form of a field effect transistor (e.g., in the case of a charge storing memory cell), in an embodiment, the respective gate terminal is coupled to the row control line 206 and a first source/drain terminal is coupled to a first column control line 210. A second source/drain terminal may be coupled to a second column control line 210. Alternatively, with a first source/drain terminal of an adjacent memory cell, which may then, e.g., also be coupled to the same row control line 206 (this is the case, e.g., in a NAND arrangement of the memory cells in the memory cell field 202).

In an embodiment, by way of example, for reading or for programming, a single row control line 206 and a single column control line 210 are selected at the same time and are appropriately driven for reading or programming of the thus selected memory cell. In an alternative embodiment, it may be provided to respectively select a single row control line 206 a plurality of column control lines 210 at the same time for reading or for programming, thereby allowing to read or program a plurality of memory cells at the same time.

Furthermore, in an embodiment, the memory 124 includes at least one write buffer memory 212 and at least one read buffer memory 214. The at least one write buffer memory 212 and the at least one read buffer memory 214 are coupled with the column decoder circuit 208. Depending on the type of memory cell, reference memory cells 216 may be provided for reading the memory cells.

In order to program (e.g., write) a memory cell, the data to be programmed may be received by a data register 218, which is coupled with the data write connection 128, by means of the data write connection 128, and may be buffered in the at least one write buffer memory 212 during the write operation.

In order to read a memory cell, the data read from the addressed memory cell (represented, e.g., by means of an electrical current, which flows through the addressed memory cell and the corresponding column control line 210, which may be compared with a current threshold value in order to determine the content of the memory cell, wherein the current threshold value may, e.g., be dependent on the reference memory cells 216) are, e.g., buffered in the read buffer memory 214 during the read operation. The result of the comparison and therewith the logic state of the memory cell (wherein the logic state of the memory cell represents the memory content of the memory cell) may then be stored in the data register 218 and may be provided via the data read connection 130, with which the data register 218 may be coupled.

The access operations (e.g., write operations, read operations, or erase operations) may be controlled by a memory-internal controller 220, which in turn may be controlled by the memory cell arrangement controller 122 by means of the bidirectional control/state connection 132. In an alternative embodiment, the data register 218 may directly be connected to the memory cell arrangement controller 122 by means of the bidirectional control/state connection 132 and thus directly controlled thereby. In this example, the memory-internal controller 220 may be omitted.

In an embodiment, the memory cells of the memory cell field may be grouped into memory blocks or memory sectors, which may be commonly erased in an erase operation. In an embodiment, there are so many memory cells included in a memory block or memory sector such that the same amount of data may be stored therein as compared with a conventional hard disk memory sector (e.g., 512 byte), although a memory block or memory sector may alternatively also store another amount of data.

Furthermore, other common memory components (e.g., peripheral circuits such as, e.g., charge pump circuits, etc.) may be provided in the memory 124, but they are neither shown in FIG. 1 nor FIG. 2 for reasons of clarity.

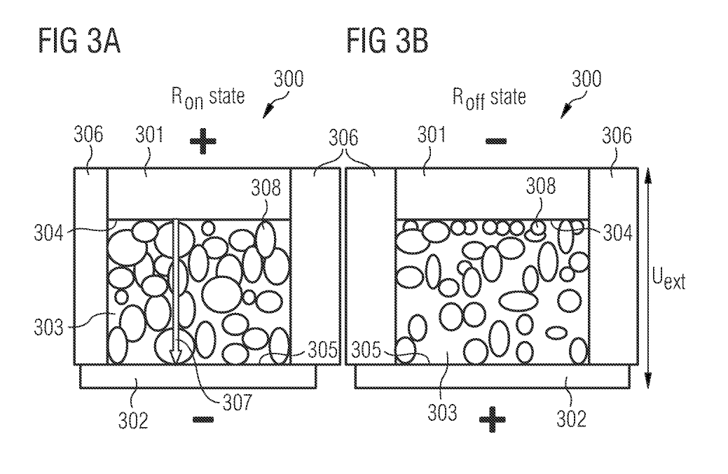

FIGS. 3A and 3B show an example of a memory cell in more detail, wherein the memory cell may be configured as a solid electrolyte memory cell such as, e.g., a programmable metallization cell (PMC) (e.g., also referred to as a CBRAM (conductive bridging random access memory) memory cell).

As shown in FIG. 3A, a CBRAM cell 300 may include a first electrode 301 a second electrode 302, and a solid electrolyte block (in the following also referred to as ion conductor block) 303 which includes the active material and which is sandwiched between the first electrode 301 and the second electrode 302. This solid electrolyte block 303 can also be shared between a plurality of memory cells (not shown here). The first electrode 301 may contact a first surface 304 of the ion conductor block 303, the second electrode 302 may contact a second surface 305 of the ion conductor block 303. The ion conductor block 303 may be isolated against its environment by an isolation structure 306. The first surface 304 may be the top surface and the second surface 305 may be the bottom surface of the ion conductor 303. In the same way, the first electrode 301 may be the top electrode, and the second electrode 302 may be the bottom electrode of the CBRAM cell. One of the first electrode 301 and the second electrode 302 may be a reactive electrode, the other one may be an inert electrode. In this example, the first electrode 301 may be the reactive electrode, and the second electrode 302 may be the inert electrode. In this example, the first electrode 301 may include silver (Ag), the ion conductor block 303 may include silver-doped chalcogenide material, the second electrode 302 may include tungsten (W), and the isolation structure 306 may include SiO₂ or Si₃N₄. The various embodiments are however not restricted to these materials. For example, the first electrode 301 may alternatively or additionally include copper (Cu) or zinc (Zn), and the ion conductor block 303 may alternatively or additionally include copper-doped chalcogenide material. Further, the second electrode 302 may alternatively or additionally include nickel (Ni) or platinum (Pt), iridium (Ir), rhenium (Re), tantalum (Ta), titanium (Ti), ruthenium (Ru), molybdenum (Mo), vanadium (V), conductive oxides, silicides, and nitrides of the aforementioned materials, and can also include alloys of the aforementioned materials. The thickness of the ion conductor 303 may, for example, range between about 5 nm and about 500 nm. The thickness of the first electrode 301 may, for example, range between about 10 nm and about 100 nm. The thickness of the second electrode 302 may, for example, range between about 5 nm and about 500 nm, between about 15 nm to about 150 nm, or between about 25 nm and about 100 nm. It is to be understood that the embodiments are not restricted to the above-mentioned materials and thicknesses.

In the context of this description, chalcogenide material (ion conductor) may be understood for example as any compound containing oxygen, sulphur, selenium, germanium and/or tellurium. In accordance with one embodiment of the invention, the ion conducting material is for example a compound, which is made of a chalcogenide and at least one metal of the group I or group II of the periodic system, for example, arsenic-trisulfide-silver. Alternatively, the chalcogenide material may contain germanium-sulfide (GeSₓ), germanium-selenide (GeSeₓ), tungsten oxide (WOₓ), copper sulfide (CuSₓ) or the like. The ion conducting material may be a solid state electrolyte. Furthermore, the ion conducting material can be made of a chalcogenide material containing metal ions, wherein the metal ions can be made of a metal, which is selected from a group consisting of silver, copper and zinc or of a combination or an alloy of these metals.

If a voltage as indicated in FIG. 3A is applied across the ion conductor block 303, a redox reaction is initiated which drives Ag⁺ ions out of the first electrode 301 into the ion conductor block 303 where they are reduced to Ag, thereby forming Ag rich clusters 308 within the ion conductor block 303. If the voltage applied across the ion conductor block 303 is applied for an enhanced period of time, the size and the number of Ag rich clusters within the ion conductor block 303 is increased to such an extent that a conductive bridge 307 between the first electrode 301 and the second electrode 302 is formed. In case that a voltage is applied across the ion conductor 303 as shown in FIG. 3B (inverse voltage compared to the voltage applied in FIG. 3A), a redox reaction is initiated which drives Ag⁺ ions out of the ion conductor block 303 into the first electrode 301 where they are reduced to Ag. As a consequence, the size and the number of Ag rich clusters 308 within the ion conductor block 303 is reduced, thereby erasing the conductive bridge 307. After having applied the voltage/inverse voltage, the memory cell 300 remains within the corresponding defined switching state even if the voltage/inverse voltage has been removed.

In order to determine the current memory status of a resistive memory cell such as, e.g., a CBRAM cell, for example, a sensing current is routed through the resistive memory cell such as, e.g., a CBRAM cell. The sensing current experiences a high resistance, e.g., in case no conductive bridge 307 exists within the CBRAM cell, and experiences a low resistance in case a conductive bridge 307 exists within the CBRAM cell. A high resistance may, for example, represent a first logic state “0”, whereas a low resistance represents a second logic “1”, or vice versa. The memory status detection may also be carried out using sensing voltages. Alternatively, a sensing voltage may be used in order to determine the current memory status of the resistive memory cell such as, e.g., a CBRAM cell.

According to another implementation, the resistivity changing memory cells of the memory cell field 202 may be phase changing memory cells that include a phase changing material. The phase changing material can be switched between at least two different crystallization states (i.e., the phase changing material may adopt at least two different degrees of crystallization), wherein each crystallization state may be used to represent a memory state. When the number of possible crystallization states is two, the crystallization state having a high degree of crystallization is also referred to as a “crystalline state”, whereas the crystallization state having a low degree of crystallization is also referred to as an “amorphous state”. Different crystallization states can be distinguished from each other by their differing electrical properties, and in particular by their different resistances. For example, a crystallization state having a high degree of crystallization (ordered atomic structure) generally has a lower resistance than a crystallization state having a low degree of crystallization (disordered atomic structure). For sake of simplicity, it will be assumed in the following that the phase changing material can adopt two crystallization states (an “amorphous state” and a “crystalline state”), however it will be understood that additional intermediate states may also be used.

Phase changing memory cells may change from the amorphous state to the crystalline state (and vice versa) due to temperature changes of the phase changing material. These temperature changes may be caused using different approaches. For example, a current may be driven through the phase changing material (or a voltage may be applied across the phase changing material). Alternatively, a current or a voltage may be fed to a resistive heater which is disposed adjacent to the phase changing material. To determine the memory state of a resistivity changing memory cell, a sensing current may be routed through the phase changing material (or a sensing voltage may be applied across the phase changing material), thereby sensing the resistivity of the resistivity changing memory cell, which represents the memory state of the memory cell.

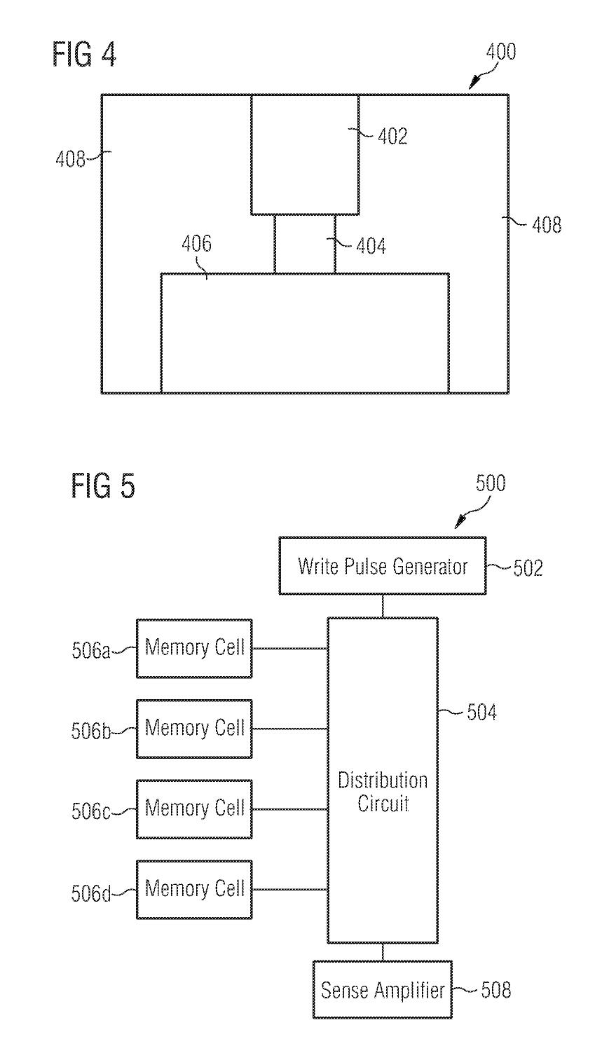

FIG. 4 illustrates a cross-sectional view of an exemplary phase changing memory cell 400 (active-in-via type) as another example of a memory cell which may be provided in the memory cell field 202 in accordance with an embodiment.

The phase changing memory cell 400 may include a first electrode 402, a phase changing material 404, a second electrode 406, and an insulating material 408. The phase changing material 404 is laterally enclosed by the insulating material 408. To use the phase changing memory cell, a selection device (not shown), such as a transistor, a diode, or another active device, may be coupled to the first electrode 402 or to the second electrode 406 to control the application of a current or a voltage to the phase changing material 404 via the first electrode 402 and/or the second electrode 406. To set the phase changing material 404 to the crystalline state, a current pulse and/or voltage pulse may be applied to the phase changing material 404, wherein the pulse parameters are chosen such that the phase changing material 404 is heated above its crystallization temperature, while keeping the temperature below the melting temperature of the phase changing material 404. To set the phase changing material 404 to the amorphous state, a current pulse and/or voltage pulse may be applied to the phase changing material 404, wherein the pulse parameters are chosen such that the phase changing material 404 is quickly heated above its melting temperature, and is quickly cooled.

The phase changing material 404 may include a variety of materials. According to one embodiment, the phase changing material 404 may include or consist of a chalcogenide alloy that includes one or more elements from group VI of the periodic table. According to another embodiment, the phase changing material 404 may include or consist of a chalcogenide compound material, such as GeSbTe, SbTe, GeTe or AgInSbTe. According to a further embodiment, the phase changing material 402 may include or consist of chalcogen free material, such as GeSb, GaSb, InSb, or GeGaInSb. According to still another implementation, the phase changing material 402 may include or consist of any suitable material including one or more of the elements Ge, Sb, Te, Ga, Bi, Pb, Sn, Si, P, O, As, In, Se, and S.

According to one example, at least one of the first electrode 402 and the second electrode 406 may include or consist of Ti, V, Cr, Zr, Nb, Mo, Hf, Ta, W, or mixtures or alloys thereof. According to another example, at least one of the first electrode 402 and the second electrode 406 may include or consist of Ti, V, Cr, Zr, Nb, Mo, Hf, Ta, W and two or more elements selected from the group consisting of B, C, N, O, Al, Si, P, S, and/or mixtures and alloys thereof. Examples of such materials include TiCN, TiAlN, TiSiN, W—Al₂O₃ and Cr—Al₂O₃.

FIG. 5 illustrates a block diagram of a portion 500 of the memory 124 in accordance with an implementation. In this implementation, the portion 500 of the memory 124 may include a write pulse generator 502 (which may be part of the memory-internal controller 220), a distribution circuit 504 (which may also be part of the memory-internal controller 220), phase changing memory cells 506a, 506b, 506c, 506d (for example, being configured as phase changing memory cells 400 as shown in FIG. 4) (e.g., in the memory cell field 202), and a sense amplifier 508 (which may be part of the read buffer memory 214, for example). According to an implementation, the write pulse generator 502 generates current pulses or voltage pulses that are supplied to the phase changing memory cells 506a, 506b, 506c, 506d via the distribution circuit 504, thereby programming the memory states of the phase changing memory cells 506a, 506b, 506c, 506d. According to one implementation, the distribution circuit 504 includes a plurality of transistors that supply direct current pulses or direct voltage pulses to the phase changing memory cells 506a, 506b, 506c, 506d or to heaters being disposed adjacent to the phase changing memory cells 506a, 506b, 506c, 506d.

As already indicated, the phase changing material of the phase changing memory cells 506a, 506b, 506c, 506d may be changed from the amorphous state to the crystalline state (or vice versa) under the influence of a temperature change. More generally, the phase changing material may be changed from a first degree of crystallization to a second degree of crystallization (or vice versa) under the influence of a temperature change. For example, a bit value “0” may be assigned to the first (low) degree of crystallization, and a bit value “1” may be assigned to the second (high) degree of crystallization. Since different degrees of crystallization imply different electrical resistances, the sense amplifier 508 is capable of determining the memory state of one of the phase changing memory cells 506a, 506b, 506c, or 506d in dependence on the resistance of the phase changing material.

To achieve high memory densities, the phase changing memory cells 506a, 506b, 506c, 506d may be capable of storing multiple bits of data, i.e., the phase changing material may be programmed to more than two resistance values. For example, if a phase changing memory cell 506a, 506b, 506c, 506d is programmed to one of three possible resistance levels, about 1.5 bits of data per memory cell can be stored. If the phase changing memory cell is programmed to one of four possible resistance levels, two bits of data per memory cell can be stored, and so on.

The example shown in FIG. 5 may also be applied in a similar manner to other types of resistivity changing memory cells like programmable metallization cells (PMCs), magneto-resistive memory cells (e.g., MRAMs), organic memory cells (e.g., ORAMs), or transition oxide memory cells (TMOs).

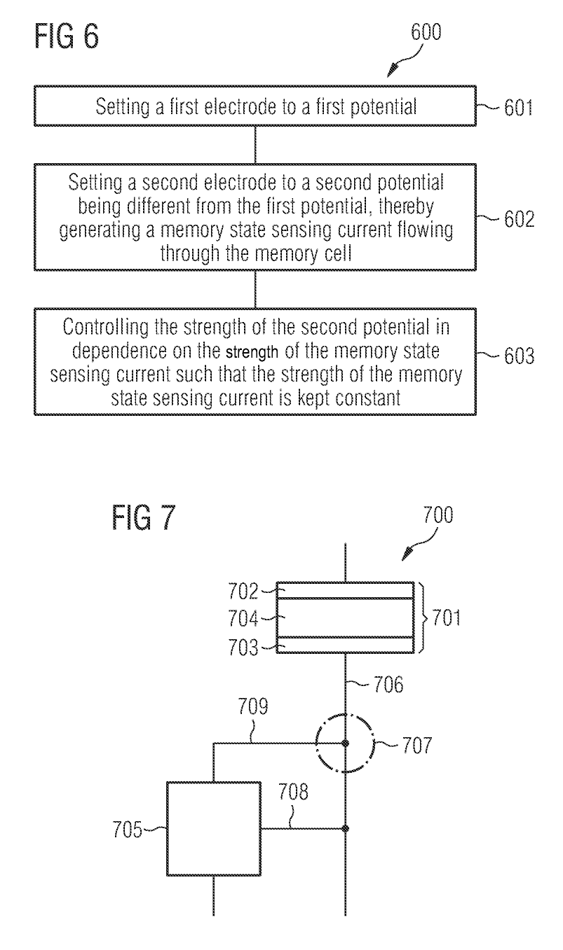

FIG. 6 shows a method 600 of determining a memory state of a memory cell. The memory cell may include a first electrode, a second electrode, and a resistivity changing layer being disposed between the first electrode and the second electrode.

At 601, a first electrode of the memory cell is set to a first potential.

At 602, the second electrode of the memory cell is set to a second potential being different from the first potential, thereby generating a memory state sensing current flowing through the memory cell.

At 603, the strength of the second potential is controlled in dependence on the strength of the memory sensing current such that the strength of the memory state sensing current is kept constant.

A constant memory state sensing current enables to improve the sensitivity of the memory state determining processes. Thus, also very small memory cell resistances can be detected.

In order to control the current strength of the memory state sensing current to a constant value at 603, several possibilities exist. For example, according to one implementation, the strength of the first potential may be kept fixed (e.g., set to mass potential), wherein the strength of the second potential may be controlled to a constant value.

According to another implementation, the memory state sensing current is routed to the resistivity changing memory cell via a current line which is connected to the second electrode. In order to control the strength of the second potential, the strength of a third potential of a section of the current line is controlled at 603.

According to another implementation, the current line may include a bit line section and a master bit line section, wherein the section of the current line which is controlled to the third potential is a part of the master bit line section.

According to an example, the master bit line section includes a switch, wherein the transmittance of the switch is increased if the sensing current strength decreases, and wherein the transmittance of the switch is decreased if the sensing current strength increases.

FIG. 7 shows a memory device 700 according to an embodiment. The memory device 700 may include a resistivity changing memory cell 701 including a first electrode 702, a second electrode 703, and a resistivity changing layer 704 being disposed between the first electrode 702 and the second electrode 703, wherein the first electrode 702 is set to a first potential. The memory device 700 may further include a setting circuit 705 which may be configured to set the second electrode 703 to a second potential being different from the first potential of the first electrode 702. In this way, the setting circuit 705 is capable of generating a memory state sensing current which flows through the resistivity changing memory cell 701. The setting circuit 705 may further be configured to control the strength of the second potential of the second electrode 703 in dependence on the strength of the memory state sensing current such that the strength of the memory state sensing current is kept constant.

According to an example, the strength of the first potential of the first electrode 702 is constant, wherein the setting circuit 705 is configured to control the second potential of the second electrode 705 such that its strength is kept constant, i.e., the potential difference of the first electrode 702 and the second electrode 703 is controlled to a constant value.

According to an example, the memory device 700 may include a current line 706, which is connected to the second electrode 703. The current line 706 is part of a memory state sensing current path used for routing the memory state sensing current through the resistivity changing memory cell 701. The setting circuit 705 is configured to control the strength of a third potential of a section 707 of the current line.

According to an example, the current line 706 may include a bit line section and a master bit line section, wherein the section 707 which is controlled to the third potential is a part of the master bit line section. According to an example, the master bit line section may include a switch, wherein the setting circuit 705 may be configured to increase the transmittance of the switch if the sensing current strength decreases, and to decrease the transmittance of the switch if the sensing current strength increases.

According to an example, the resistivity changing memory cell 701 is a programmable metallization cell (PMC), for example, a conductive bridging random access memory (CBRAM) cell. Alternatively, the resistivity changing memory cell 701 may be a phase changing memory cell (e.g. a phase changing random access memory (PCRAM) cell).

According to an example, the setting circuit 705 may be configured to control the third potential within the section 707 of the current line 706 by measuring the strength of the current flowing through the current line 706 using an electrical connection 708, and by supplying a corresponding controlling voltage to the section 707 via a further electrical connection 709.

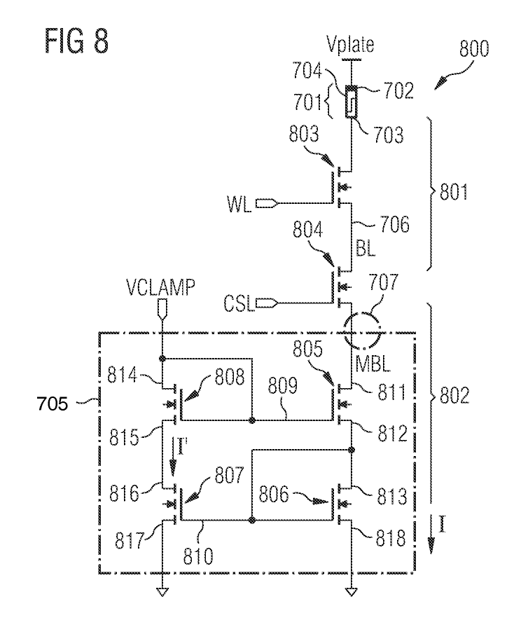

FIG. 8 shows a memory device 800 including a resistivity changing memory cell having a first electrode 702, a second electrode 703 and a resistivity changing layer 704 being disposed between the first electrode 702 and the second electrode 703. The second electrode 703 may be connected to a current line 706 which includes a bit line section 801 and a master bit line section 802. A word line switch 803 and a common source line switch 804 are connected into the current line 706. The memory device 800 may further include a setting circuit 705. The setting circuit 705 may include a first transistor 805, a second transistor 806, a third transistor 807, and a fourth transistor 808. The gate region of the first transistor 805 may be connected to the gate region of the fourth transistor 808 via a first connection 809, and the gate region of the second transistor 806 is connected to the gate region of the third transistor 807 via a second connection 810. The first transistor 805 and the second transistor 806 are connected into the master bit line section such that a first source/drain region 811 of the first transistor 805 is connected to the section 707 of the master bit line section 802 which is controlled to the third potential. A second source/drain region 812 of the first transistor 805 is connected to a first source/drain region 813 of the second transistor 806 and the second connection 810. A first source/drain region 814 of the fourth transistor 808 is connected to a fourth potential “vclamp”, which is fixed, and is connected to the first connection 809. The second source/drain region 815 of the fourth transistor 808 is connected to a first source/drain region 816 of the third transistor 807. The second source/drain region 817 of the third transistor 807 is connected to ground. The second source/drain region 818 of the second transistor 806 is connected to ground.

In the following, one effect of the setting circuit 705 will be explained in more detail. It is assumed that a current I flows through the current line 706 and the resistivity changing memory cell 701 in order to determine the memory state of the resistivity changing memory cell 701. The strength of the current I flowing through the current line 706 is limited by the first transistor 805. If the strength of the current I increases, the transmittance of the third transistor 807 will increase. As a consequence, the strength of a current I′ flowing through the third transistor 807 and the fourth transistor 808 will increase. As a consequence, the transmittance of the first transistor 805 will be reduced. Thus, the strength of the current I decreases again. A decrease of the current I, however, results in a reduced transmittance of the third transistor 807. As a consequence, the strength of the current I′ decreases, and the transmittance of the first transistor 805 is increased again. In this way, the current line section 707 is controlled to the potential “vclamp”. Assuming that this first electrode 702 is set to a fixed potential, a constant potential difference results between the first electrode 702 and the second electrode 703. As a consequence, the strength of the current I is controlled to a constant value. In this way, the strength of the current I is used in order to set the potential difference between the first electrode 702 and the second electrode 703 to a constant value. Thus, it is possible to read out small cell resistances of the resistivity changing memory cell 701.

It is to be understood that various embodiments also provide integrated circuits having a plurality of memory devices 800 or a plurality of memory devices 700, which may be arranged as memory cell arrays. Such memory cell arrays show a high integration depth since the setting circuit 705 requires only little space.

According to an embodiment, a new concept of bit line current controlling is thus presented. In an example, the memory cell current may be used for feedback.

An example of a current feedback controlling circuit is shown in FIG. 8. “VCLAMP” is the voltage to which the master bit line is to be set. Using the two current mirrors in the setting means, the master bit line voltage is forced to be controlled to the same potential as VCLAMP.

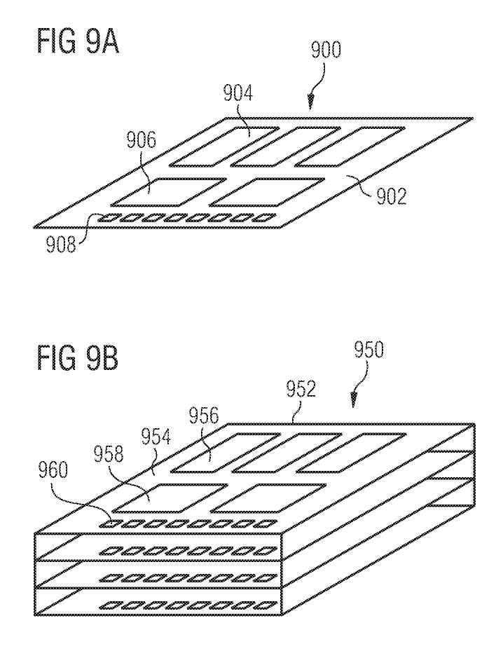

As shown in FIGS. 9A and 9B, in some embodiments, memory devices/integrated circuits such as those described herein may be used in modules.

In FIG. 9A, a memory module 900 is shown, on which one or more memory devices/integrated circuits 904 are arranged on a substrate 902. The memory devices/integrated circuits 904 include numerous memory cells. The memory module 900 may also include one or more electronic devices 906, which may include memory, processing circuitry, control circuitry, addressing circuitry, bus interconnection circuitry, or other circuitry or electronic devices that may be combined on a module with a memory device/integrated circuit, such as the integrated circuits/memory devices 904. Additionally, the memory module 900 may include multiple electrical connections 908, which may be used to connect the memory module 900 to other electronic components, including other modules.

As shown in FIG. 9B, in some embodiments, these modules may be stackable, to form a stack 950. For example, a stackable memory module 952 may contain one or more integrated circuits/memory devices 956, arranged on a stackable substrate 954. The integrated circuits/memory devices 956 include memory cells. The stackable memory module 952 may also include one or more electronic devices 958, which may include memory, processing circuitry, control circuitry, addressing circuitry, bus interconnection circuitry, or other circuitry or electronic devices that may be combined on a module with a memory device, such as the memory devices/integrated circuits 956. Electrical connections 960 are used to connect the stackable memory module 952 with other modules in the stack 950, or with other electronic devices. Other modules in the stack 950 may include additional stackable memory modules, similar to the stackable memory module 952 described above, or other types of stackable modules, such as stackable processing modules, control modules, communication modules, or other modules containing electronic components.

In another example, another type of resistivity changing memory cell may be used as memory cells in the memory cell field 202, which may be formed using carbon as a resistivity changing material. In this type of memory cell, amorphous carbon that is rich in sp³-hybridized carbon (i.e., tetrahedrally bonded carbon) has a high resistivity, while amorphous carbon that is rich in sp²-hybridized carbon (i.e., trigonally bonded carbon) has a low resistivity. This difference in resistivity can be used in a resistivity changing memory cell.

In an example, a carbon memory cell may be formed in a manner similar to that described above with reference to phase changing memory cells. A temperature-induced change between an sp³-rich state and an sp²-rich state may be used to change the resistivity of an amorphous carbon material. These differing resistivities may be used to represent different memory states. For example, a high resistance sp³-rich state can be used to represent a “0”, and a low resistance sp²-rich state can be used to represent a “1”. It will be understood that intermediate resistance states may be used to represent multiple bits, as discussed above.

In this type of carbon memory cell, application of a first temperature may cause a change of high resistivity sp³-rich amorphous carbon to relatively low resistivity sp²-rich amorphous carbon. This conversion can be reversed by application of a second temperature, which is typically higher than the first temperature. As discussed above, these temperatures may be provided, for example, by applying a current and/or voltage pulse to the carbon material. Alternatively, the temperatures can be provided by using a resistive heater that is disposed adjacent to the carbon material.

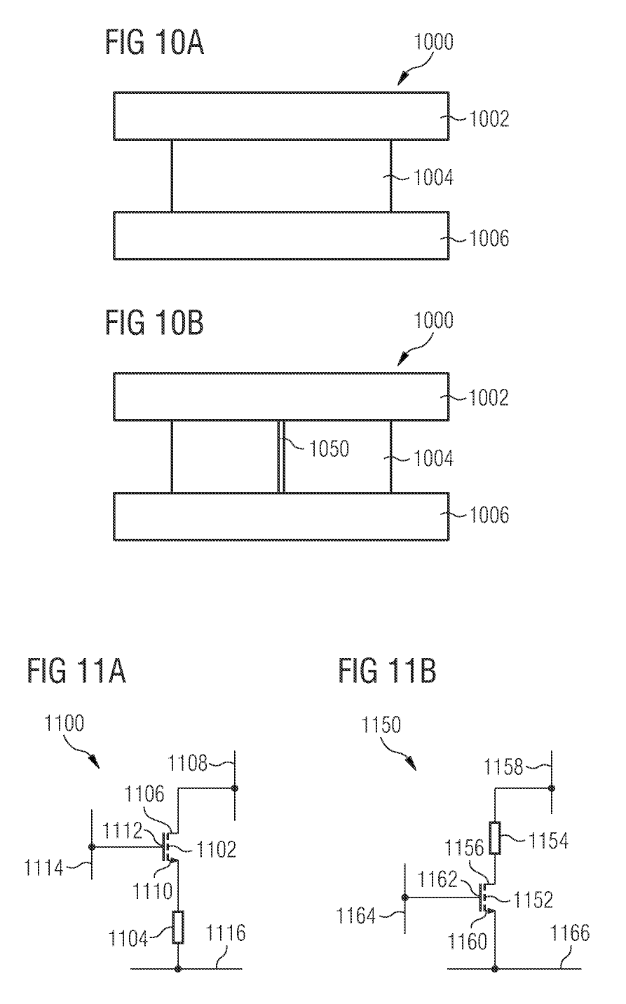

Another way in which resistivity changes in amorphous carbon can be used to store information is by field-strength induced growth of a conductive path in an insulating amorphous carbon film. For example, applying voltage or current pulses may cause the formation of a conductive sp² filament in insulating sp³-rich amorphous carbon. The operation of this type of resistive carbon memory is illustrated in FIGS. 10A and 10B.

FIG. 10A shows a carbon memory cell 1000 that includes a top contact 1002, a carbon storage layer 1004 including an insulating amorphous carbon material rich in sp³-hybridized carbon atoms, and a bottom contact 1006. As shown in FIG. 10B, by forcing a current (or voltage) through the carbon storage layer 1004, an sp² filament 1050 can be formed in the sp³-rich carbon storage layer 1004, changing the resistivity of the memory cell. Application of a current (or voltage) pulse with higher energy (or, in some embodiments, reversed polarity) may destroy the sp² filament 1050, increasing the resistance of the carbon storage layer 1004. As discussed above, these changes in the resistance of the carbon storage layer 1004 can be used to store information, with, for example, a high resistance state representing a “0” and a low resistance state representing a “1”. Additionally, in some embodiments, intermediate degrees of filament formation or formation of multiple filaments in the sp³-rich carbon film may be used to provide multiple varying resistivity levels, which may be used to represent multiple bits of information in a carbon memory cell. In some embodiments, alternating layers of sp³-rich carbon and sp²-rich carbon may be used to enhance the formation of conductive filaments through the sp³-rich layers, reducing the current and/or voltage that may be used to write a value to this type of carbon memory.

Resistivity changing memory cells, such as the phase changing memory cells and carbon memory cells described above, may be used as part of a memory cell, along with a transistor, diode, or other active component for selecting the memory cell. FIG. 11A shows a schematic representation of such a memory cell that uses a resistivity changing memory element. The memory cell 1100 includes a select transistor 1102 and a resistivity changing memory element 1104. The select transistor 1102 includes a source 1106 that is connected to a bit line 1108, a drain 1110 that is connected to the memory element 1104, and a gate 1112 that is connected to a word line 1114. The resistivity changing memory element 1104 is also connected to a common line 1116, which may be connected to ground, or to other circuitry, such as circuitry (not shown) for determining the resistance of the memory cell 1100, for use in reading. Alternatively, in some configurations, circuitry (not shown) for determining the state of the memory cell 1100 during reading may be connected to the bit line 1108. It should be noted that as used herein the terms connected and coupled are intended to include both direct and indirect connection and coupling, respectively.

To write to the memory cell 1100, the word line 1114 may be used to select the memory cell 1100, and a current (or voltage) pulse on the bit line 1108 is applied to the resistivity changing memory element 1104, changing the resistance of the resistivity changing memory element 1104. Similarly, when reading the memory cell 1100, the word line 1114 is used to select the cell 1100, and the bit line 1108 may be used to apply a reading voltage (or current) across the resistivity changing memory element 1104 to measure the resistance of the resistivity changing memory element 1104.

The memory cell 1100 may be referred to as a 1T1J cell, because it uses one transistor, and one memory junction (the resistivity changing memory element 1104). Typically, a memory device will include an array of many such cells. It will be understood that other configurations for a 1T1J memory cell, or configurations other than a 1T1J configuration may be used with a resistivity changing memory element. For example, in FIG. 11B, an alternative arrangement for a 1T1J memory cell 1150 is shown, in which a select transistor 1152 and a resistivity changing memory element 1154 have been repositioned with respect to the configuration shown in FIG. 11A. In this alternative configuration, the resistivity changing memory element 1154 is connected to a bit line 1158, and to a source 1156 of the select transistor 1152. A drain 1160 of the select transistor 1152 is connected to a common line 1166, which may be connected to ground, or to other circuitry (not shown), as discussed above. A gate 1162 of the select transistor 1152 is controlled by a word line 1164.

In the following description, further features of the embodiments will be explained.

According to one embodiment, a method of controlling a master bit line voltage is presented. A current feedback controlling circuit may be used which controls the master bit line voltage using the cell current. One effect of this embodiment is that small cell resistances can be read out with less difficulty. Further, this controlling circuit may be configured using only a few transistors which only require a small area on the chip.

According to one embodiment of the present invention, a method of determining a memory state of a memory cell, e.g., of a resistivity changing memory cell, is provided. In an example, the memory cell may include a first electrode, a second electrode and a resistivity changing layer being disposed between the first electrode and the second electrode. In accordance with the method, a first electrode of the memory cell is set to a first potential and the second electrode of the memory cell is set to a second potential being different from the first potential, thereby generating a memory state sensing current flowing through the memory cell, e.g., the resistivity changing memory cell. The method may further include controlling the strength of the second potential in dependence on the strength of the memory state sensing current such that the strength of the memory state sensing current is kept constant.

According to an embodiment, the strength of the first potential is constant, and the second potential is controlled such that its strength is kept constant.

According to an embodiment, the memory state sensing current is routed to the resistivity changing memory cell via a current line which is connected to the second electrode, wherein, in order to control the strength of the second potential, the strength of a third potential of a section of the current line is controlled.

According to another embodiment, the current line includes a bit line section and a master bit line section, wherein the section of the current line which is controlled to the third potential is part of the master bit line section.

According to an embodiment, the master bit line section includes a switch, wherein the transmittance of the switch is increased if the sensing current strength decreases, and wherein the transmittance of the switch is decreased if the sensing current strength increases.

According to an embodiment, the resistivity changing memory cell is a programmable metallization cell.

According to an embodiment, the resistivity changing memory cell is a solid electrolyte memory cell.

According to an embodiment, the resistivity changing memory cell is a phase changing memory cell.

According to an embodiment, an integrated circuit including at least one memory device is provided, wherein the at least one memory device may include a resistivity changing memory cell including a first electrode, a second electrode and a resistivity changing layer being disposed between the first electrode and the second electrode. The integrated circuit may further include a setting circuit being configured to set the first electrode to a first potential, to set the second electrode to a second potential being different from the first potential in order to generate a memory state sensing current which flows through the memory cell, and to control the strength of the second potential in dependence on the strength of the memory state sensing current such that the strength of the memory state sensing current is kept constant.

According to an embodiment, the strength of the first potential is constant, wherein the setting circuit is configured to control the second potential such that its strength is kept constant.

According to an embodiment, a current line is connected to the second electrode, and is part of a memory state sensing current path used for routing a memory state sensing current to the memory cell, e.g., the resistivity changing memory cell, wherein the setting circuit is configured to control the strength of a third potential of a section of the current line.

According to an embodiment, the current line includes a bit line section and a master bit line section, wherein the section which is controlled to the third potential is a part of the master bit line section.

According to an embodiment, the master bit line section includes a switch, wherein the setting circuit may be configured to increase the transmittivity of the switch if the sensing current strength decreases, and to decrease the transmittivity of the switch if the sensing current strength increases.

According to an embodiment, the resistivity changing memory cell is a programmable metallization cell.

According to another embodiment, the resistivity changing memory cell is a solid electrolyte memory cell.

According to yet another embodiment, the resistivity changing memory cell is a phase changing memory cell.

According to yet another embodiment, the resistivity changing memory cell is a carbon memory cell.

According to an embodiment, the setting circuit may include a first transistor, a second transistor, a third transistor, and a fourth transistor, wherein the gate region of the first transistor is connected to the gate region of the fourth transistor via a first connection, and wherein the gate region of the second transistor is connected to the gate region of the third transistor via a second connection; wherein the first transistor and the second transistor are connected into the master bit line section such that a first source/drain region of the first transistor is connected to the section of the master bit line section which is controlled by the third potential, and that a second source/drain region of the first transistor is connected to a first source/drain region of the second transistor and the second connection; wherein a first source/drain region of the fourth transistor is connected to a fourth potential which is fixed, and is connected to the first connection, and wherein the second source/drain region of the fourth transistor is connected to a first source/drain region of the third transistor; wherein the second source/drain region of the third transistor is connected to a fifth potential which is fixed; and wherein the second source/drain region of the second transistor is connected to the fifth potential.

According to another embodiment, the fifth potential is ground potential.

According to an embodiment, the fifth potential is an internal voltage.

According to an embodiment, a memory device is provided, including: a resistivity changing memory means, which may including a first electrode means, a second electrode means and a resistivity changing means being disposed between the first electrode means and the second electrode means, a setting means for setting the first electrode means to a first potential, for setting the second electrode to a second potential being different from the first potential, thereby generating a memory state sensing current which flows through the memory means, and for controlling the strength of the second potential in dependence on the strength of the memory state sensing current such that the strength of the memory state sensing current is kept constant.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A method of determining a memory state of a memory cell, the method comprising:
setting a first electrode of the memory cell to a first potential;
setting a second electrode of the memory cell to a second potential that is different from the first potential, thereby generating a memory state sensing current flowing through the memory cell; and
controlling the strength of the second potential in dependence on the strength of the memory state sensing current such that the strength of the memory state sensing current is kept substantially constant.

2. The method according to claim 1, wherein the strength of the first potential is constant, and wherein the second potential is controlled such that its strength is kept constant.

3. The method according to claim 1, wherein the memory state sensing current is routed to the memory cell via a current line that is connected to the second electrode, and wherein, in order to control the strength of the second potential, the strength of a third potential of a section of the current line is controlled.

4. The method according to claim 3, wherein the current line comprises a bit line section and a master bit line section, and wherein the section of the current line that is controlled to the third potential is a part of the master bit line section.

5. The method according to claim 4, wherein the master bit line section comprises a switch, wherein a transmittance of the switch is increased if the sensing current strength decreases, and wherein the transmittance of the switch is decreased if the sensing current strength increases.

6. The method according to claim 1, wherein the memory cell comprises a resistivity changing memory cell.

7. The method according to claim 6, wherein the resistivity changing memory cell is a programmable metallization cell.

8. The method according to claim 6, wherein the resistivity changing memory cell is a solid electrolyte memory cell.

9. The method according to claim 6, wherein the resistivity changing memory cell is a phase changing memory cell.

10. An integrated circuit comprising at least one memory device, the integrated circuit comprising:
a memory cell; and
a setting circuit configured to:
set a first electrode of the memory cell to a first potential;
set a second electrode of the memory cell to a second potential that is different from the first potential, in order to generate a memory state sensing current that flows through the memory cell; and
control the strength of the second potential in dependence on the strength of the memory state sensing current such that the strength of the memory state sensing current is kept constant.

11. The integrated circuit according to claim 10, wherein the strength of the first potential is constant, and wherein the setting circuit is configured to control the second potential such that its strength is kept constant.

12. The integrated circuit according to claim 10, further comprising:
a current line coupled to the second electrode, and which is part of a memory state sensing current path used for routing the memory state sensing current to the memory cell,
wherein the setting circuit is configured to control the strength of a third potential of a section of the current line.

13. The integrated circuit according to claim 12,
wherein the current line comprises a bit line section and a master bit line section, and
wherein the section that is controlled to the third potential is a part of the master bit line section.

14. The integrated circuit according to claim 13,
wherein the master bit line section comprises a switch,
wherein the setting circuit is configured to increase transmittivity of the switch if the sensing current strength decreases, and
wherein the setting circuit is configured to decrease transmittivity of the switch if the sensing current strength increases.

15. The integrated circuit according to claim 10, wherein the memory cell is a resistivity changing memory cell.

16. The integrated circuit according to claim 15, wherein the resistivity changing memory cell is a programmable metallization cell.

17. The integrated circuit according to claim 15, wherein the resistivity changing memory cell is a solid electrolyte memory cell.

18. The integrated circuit according to claim 15, wherein the resistivity changing memory cell is a phase changing memory cell.

19. The integrated circuit according to claim 15, wherein the resistivity changing memory cell is a carbon memory cell.

20. The integrated circuit according to claim 13,
wherein the setting circuit comprises a first transistor, a second transistor, a third transistor, and a fourth transistor,
wherein a gate region of the first transistor is connected to a gate region of the fourth transistor via a first connection, and
wherein a gate region of the second transistor is connected to a gate region of the third transistor via a second connection,
wherein the first transistor and the second transistor are connected into the master bit line section such that a first source/drain region of the first transistor is connected to the section of the master bit line section that is controlled to the third potential, and that a second source/drain region of the first transistor is connected to a first source/drain region of the second transistor and the second connection,
wherein a first source/drain region of the fourth transistor is connected to a fixed fourth potential, and is connected to the first connection, and wherein a second source/drain region of the fourth transistor is connected to a first source/drain region of the third transistor,
wherein a second source/drain region of the third transistor is connected to a fixed fifth potential, and
wherein a second source/drain region of the second transistor is connected to the fixed fifth potential.

21. The integrated circuit according to claim 20, wherein the fixed fifth potential is ground potential.

22. The integrated circuit according to claim 20, wherein the fixed fifth potential is an internal voltage.

23. A memory device, comprising:
a memory cell;
setting means for setting a first electrode of the memory cell to a first potential, for setting a second electrode of the memory cell to a second potential that is different from the first potential, thereby generating a memory state sensing current which flows through the memory means, and for controlling the strength of the second potential in dependence on the strength of the memory state sensing current such that the strength of the memory state sensing current is kept substantially constant.

24. A memory module comprising at least one memory device, the memory module comprising:
a memory cell;
a setting circuit being configured to set a first electrode of the memory cell to a first potential;
set a second electrode of the memory cell to a second potential being different from the first potential, in order to generate a memory state sensing current which flows through the memory cell; and
control the strength of the second potential in dependence on the strength of the memory state sensing current such that the strength of the memory state sensing current is kept constant.

25. The memory module according to claim 24, wherein the memory module is stackable.
